(19) United States
(12) Patent Application Publication
(10) Pub. No.: US 2007/0235077 A1
(43) Pub. Date: Oct. 11, 2007

(54) Solar Cell Module and Manufacturing Process Thereof

(75) Inventors: Masaru NAGATA, Soraku-gun (JP); Toshifumi KIYOHARA, Soraku-gun (JP); Kouji NISHI, Ise-shi (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi (JP)

(21) Appl. No.: 11/691,365

(22) Filed: Mar. 26, 2007

(30) Foreign Application Priority Data
Mar. 27, 2006 (JP) JP2006-085111
Jul. 28, 2006 (JP) JP2006-206572

(51) Int. Cl. H01L 31/00

(52) U.S. Cl. 136/256

(57) ABSTRACT

In a solar cell module, a solder fillet 19 is formed on an end surface on the shorter length side of a connection tab to be connected to a bus bar electrode 2a, 3a up to the height of the connection tab. The geometry of the solder fillet 19 is adjusted so that an indentation amount is 0-54% of the height or a bulge amount is 0-10% of the height, by which the maximum principal stress generated during the manufacturing process of a solar cell element 4 can be reduced, and therefore occurrences of cracks can be reduced. Also during a laminating process, breaking of the solar cell element or crack generation can be eliminated.

### BACKGROUND OF THE INVENTION

1. Field of the Invention

The present invention relates to a solar cell module including a plurality of solar cell elements connected to each other by means of connection tabs and a manufacturing process thereof, and in particular, to a solar cell module and a manufacturing process thereof in which yield in the manufacturing process is improved.

2. Description of Related Art

With the increasing attention to global environment issues and energy saving measures in recent years, new energy technologies utilizing natural energy have been receiving attention. As one of such technologies, systems utilizing solar energy are attracting a high level of interest, and in particular, spread of household use of photovoltaic power generation systems has been accelerated.

A solar cell element is fabricated using monocrystalline silicon or multicrystalline silicon with thickness of about 0.3-0.4 mm and size of about 150 mm square. This solar cell element includes inside thereof a PN junction at which a P layer mainly including P-type impurity such as boron and a N-type layer mainly including N-type impurity such as phosphorus are joined together.

A structure of a solar cell element is described referring to FIGS. 24-26.

A solar cell element 104 includes a semiconductor substrate 101 comprising a N-type region 105 and P-type region 106, a surface electrode 102 comprising surface bus bar electrodes 102a and surface power collecting electrodes (finger electrodes) 102b provided on one principal surface (light receiving surface) of the semiconductor substrate 101, and a non-light receiving electrode 103 comprising non-light receiving bus bar electrodes 103a and a non-light receiving power collecting electrode 103b provided on another principal surface (non-light receiving surface) of the semiconductor substrate 101.

The bus bar electrodes 102a, 103a and finger electrodes 102b are formed by screen printing silver paste on the semiconductor substrate 101, and occasionally, almost allover the surfaces of the bus bar electrodes 102a, 103a are solder coated to protect them and to facilitate attachment of connection tabs.

The finger electrodes 102b are 0.1-0.2 mm in width and a great number of them are formed for collecting photo-induced carriers in parallel to the sides of the solar cell element 104.

The bus bar electrodes 102a are electrodes for extracting the carriers collected by the finger electrodes 102b, and formed to have a width of about 2 mm so as to orthogonally cross the finger electrodes 102b, the number of which is 2 or so per one solar cell element.

Since this solar cell element 104 is vulnerable to physical impacts, and needs to be protected from rain and the like when installed outdoors. In addition, because one solar cell element 104 can generate only a small amount of electric power, it is necessary to electrically connect a plurality of solar cell elements 104 in series or in parallel. Accordingly, it is a general practice to interconnect a plurality of solar cell elements 104 in series or in parallel through connection tabs, and to encapsulate the connected solar cell elements 104 between a translucent substrate and a non-light receiving surface sheet with a filler, thereby fabricating a solar cell module.

Specifically, as shown in FIG. 27, a solar cell module includes a plurality of solar cell elements 104a, 104b, 104c, etc. electrically interconnected by means of hook-shaped connection tabs 107. The foregoing connection tabs 107 are connected such that a connection tab 104 is connected through solder (not shown) to a bus bar electrode 102a of one solar cell module 104a and a bus bar electrode 103a on the non-light receiving surface of another solar cell element 104b.

A plurality of solar cell elements 104a, 104b, 104c, etc. interconnected are encapsulated in a filler 109 composed mainly of ethylene vinyl acetate (EVA) copolymer and the like and sandwiched between a translucent member 108 and protective member 110 to constitute a solar cell module.

FIG. 28 is a plan view showing a state where connection tabs 107 are attached on bus bar electrodes 102a of a solar cell element 104.

The connection tabs 107 are formed such that a metal foil with low electrical resistance such as copper is cut into ribbon-like strips, and after the surfaces thereof are solder coated, they are cut into appropriate lengths to be used.

FIG. 29 is a cross-sectional view showing a state where connection tabs 107 are connected to bus bar electrodes 102a, 103a of a solar cell element 104 by soldering, as described above.

In this way, a connection tab 107 is attached on a bus bar electrode on the light receiving surface or non-light receiving surface of a solar cell element 104 by soldering, and the other end portion of the connection tab 107 is attached to another solar cell element 104 adjacent thereto thereby to electrically interconnect the solar cell elements 104.

When the connection tab 107 is soldered, since the melting point of solder is about 200° C., the temperature of the solar cell element 104 becomes 200° C. or higher.

For this reason, when the temperature of the solar cell element 104 returns to room temperature, the connection tab 107 shrinks. The solar cell element 104 connected to the connection tabs fails to absorb stress generated by the shrinkage of the connection tabs 107, and as a result, stress is generated in the solar cell element 104.

This stress may cause cracks to occur in the semiconductor substrate 101. In the connection areas between the connection tabs 107 and the bus bar electrodes 102a, 103a, thermal expansion (thermal shrinkage) of the connection tabs 107 is particularly great at end portions on the shorter length sides thereof, and therefore cracking is prone to occur in the semiconductor substrate 101.

FIG. 30 is a plan view showing a state where microcracks CR are generated in the vicinity of bus bar electrodes of a solar cell element 104 with connection tabs attached thereto.

When microcracks CR are generated in the solar cell element 104 as shown above, bus bar electrodes 102a, 103a may peel off the substrate of the solar cell element 104. In addition, the solar cell element 104 may break or have significant cracks during the subsequent laminate process where the solar cell element 104 is encapsulated with a filler, which causes yield in the manufacturing process of solar cell module to drop.

In particular, an increasing number of recent solar cell modules employ substantially lead-free solder for an environmentally-friendly purpose, and when this kind of substantially lead-free solder is used, due to the properties of the solder, the soldering temperature is high. For this reason, the degree of warpage in end portions of the solar cell element 104 becomes greater before and after soldering of the connection tabs 107 described above. For this reason, microcracks are more prone to generate in the solar cell element 104.

Moreover, in recent solar cell modules, the thickness of the silicon substrate used for the solar cell element 104 tends to be reduced for cost reduction. Microcracks are therefore more prone to generate in the solar cell element 104 and the degree thereof tends to be significant. According to tests that the present inventors repeatedly carried out, due to stress generated in the surface of the solar cell element 104, microcracks are prone to occur when the thickness of the solar cell element is less than 0.3 mm.

It is an object of the present invention to provide a solar cell module with stable yield by relieving stress generating in a solar cell element when connection tabs are attached to electrodes on the solar cell element.

Also, it is an object of the present invention to provide a manufacturing process of a solar cell module by which stress generating in a semiconductor substrate can be relieved.

### SUMMARY OF THE INVENTION

While reference symbols are assigned for illustration of specific embodiments of the present invention in the following description, implementation of the present invention is not limited to the embodiments.

A solar cell module according to the present invention comprises: a solar cell element including a bus bar electrode for extracting output electric current; a connection tab having a shape including shorter length sides and longer length sides, that is superposedly attached to the bus bar electrode so as to be electrically connected to the bus bar electrode; and a shorter length side-fixation member provided so as to fixate to both the bus bar electrode and an end surface on the shorter length side of the connection tab.

In the solar cell module according to the present invention, since the connection tab is superposed on the bus bar electrode so as to be connected thereto, and a shorter length side-fixation member is formed on an end surface on the shorter length side of the connection tab, stress generated in the surface of the solar cell element is dispersed by the shorter length side-fixation member and the shorter length side-fixation member itself is deformed in response to the stress. Thus, the maximum principal stress generated on the surface of the solar cell element can be relieved by the shorter length side-fixation member, so that occurrences of microcracks can be reduced, and therefore, occurrences of breaking and cracking of the solar cell element during the manufacturing process can be eliminated.

The solar cell module may further comprise a longer length side-fixation member that fixates to both side surfaces on the longer length sides of the connection tab and the bus bar electrode.

A length D of a part where the shorter length side-fixation member is in contact with the bus bar electrode is preferably greater than a length E of a part where the longer length side-fixation member is in contact with the bus bar electrode. This is because the main direction of stress generated in the surface of the solar cell element during the step for welding the connection tab to the bus bar electrode is the direction K along the longer side, and in order to relieve the stress efficiently by the shorter length side-fixation member, the length D of a part where the shorter length side-fixation member itself is in contact with the bus bar electrode is designed to be larger is advantageous. In addition, it is preferred that a length E of a part where the longer length side-fixation member is in contact with the bus bar electrode with respect to the direction of the shorter side (the direction perpendicular to the foregoing direction K of the longer side) is shorter, because in that case, the area where the bus bar electrode and the connection tab overlap increases.

It is preferred that the geometry of the shorter length side-fixation member in a vertical cross-section with respect to the direction of the longer length side has a part that is bulged upward (in +direction) or indented downward (in −direction) with respect to a straight line G that virtually connects the highest part Z of the shorter length side-fixation member in contact with the connection tab and the longest part Y of the shorter length side-fixation member in contact with the bus bar electrode with respect to the direction of the longer length side, and the longest distance L between an outer profile of the indented or bulged part and the straight line is −10% to +54% of the height A of the shorter length side-fixation member at the highest part from the bus bar electrode. With this geometry of the shorter length side-fixation member, stress generated due to shrinkage of the connection tab during the process of welding the connection tab to the bus bar electrode can be dispersed to be transferred to the solar cell element most efficiently. Moreover, since the volume of the shorter length side-fixation member is made appropriate, so that the maximum principal stress generated in the solar cell element caused by the shrinkage of the shorter length side-fixation member can be reduced. As a result, cracks are not generated in the solar cell element.

A manufacturing process of a solar cell module according to the present invention comprises: preparing a solar cell element including a bus bar electrode for extracting output electric current on one principal surface thereof; connecting a connection tab through a conductive member to the bus bar electrode by disposing the connection tab on the bus bar electrode to be apart from a shorter length side of the bus bar electrode by a predetermined distance w; supplying a material for a fixation member 19 to an end surface on the shorter length side of the connection tab on the bus bar electrode; and forming the fixation member into the form of a fillet on the side surface on the side of a shorter length side of the connection tab.

The material for the conductive member and the fixation member may comprise a solder, and the supply of the material for the fixation member may be carried out such that with the conductive member being in a molten state between the bus bar electrode and the connection tab, the bus bar electrode is pressed relative to the connection tab, thereby pushing out the conductive member. Since in this manufacturing process, a fixation member in the form of a fillet can be formed by pushing out the conductive member in a molten state to an end portion of the connection tab on the electrode thereby to supply the conductive member, the cycle time can be shortened.

The manufacturing process may further comprise forming a solder resist with poorer solder wettability than that of the bus bar electrode at a predetermined region on the bus bar electrode so that the material of the fixation member is supplied between the solder resist and the connection tab on the bus bar electrode.

In this manufacturing process, since the fixation member is held by the connection tab and the bus bar electrode with better solder wettability than that of the solder resist, a fixation member thicker than conventional ones can be formed. Therefore, when a temperature change occurs, stress caused by the difference in thermal expansion coefficient between the connection tab and the solar cell element can be relieved by the fixation member in the form of a fillet.

Meanwhile, the semiconductor substrate may be one that includes a bus bar electrode at least on one principal surface thereof, and the present invention will be suitably utilized so long as a solar cell module is produced by connecting this bus bar electrode to a connection tab.

These and other advantages, features and effects of the invention will become apparent from the following description of specific embodiments with reference to the accompanying drawings.

### BRIEF DESCRIPTION OF THE DRAWINGS

FIG. 1 is a plan view of the light receiving surface side of a solar cell element constituting a solar cell module according to the present invention.

FIG. 2 is a plan view of the non light receiving surface side of a solar cell element constituting a solar cell module according to the present invention.

FIG. 3 shows a cross-sectional structure of a solar cell element.

FIG. 4 is a cross-sectional view showing a solar cell module constructed using the foregoing solar cell element.

FIG. 5 is a plan view of the light receiving surface side of a solar cell element with connection tabs attached thereto.

FIG. 6 is an enlarged view of a region in the vicinity of an end portion of a connection tab.

FIG. 7 shows a cross section of the solar cell element taken along the line A-A′ of FIG. 5.

FIG. 8 is an enlarged cross-sectional view of an end portion of a connection tab showing a case where a fillet has an indentation in cross-sectional view.

FIG. 9 is an enlarged cross-sectional view of an end portion of a connection tab showing a case where a fillet has a protrusion in cross-sectional view.

FIG. 10 is an enlarged cross-sectional view of an end portion of a connection tab showing a case where a fillet has a protrusion grown higher than the connection tab.

FIG. 11 is a cross-sectional view showing a state where a solder coating layer is thinned in the vicinity of an end portion of a connection tab.

FIGS. 12-16 illustrate steps of a manufacturing process of a solar cell module according to one embodiment of the present invention.

FIGS. 17-21 illustrate steps of a manufacturing process of a solar cell module according to another embodiment of the present invention.

FIG. 22 is an enlarged cross-sectional view showing a state where a fillet includes a second region that is not in contact with bus bar electrodes.

FIG. 23 is a graph showing the relationship between the geometry of the fillet, stress Fx applied to the substrate directly under a point X on an electrode and stress Fy applied to the substrate directly under a point Y on the electrode.

FIG. 24 is a plan view from the light receiving surface side of a conventional solar cell element.

FIG. 25 is a plan view from the non-light receiving surface side of the conventional solar cell element.

FIG. 26 shows a cross-sectional structure of a conventional solar cell element.

FIG. 27 shows a cross-sectional structure of a conventional solar cell module.

FIG. 28 is a plan view showing a state where connection tabs are attached to bus bar electrodes of a conventional solar cell element.

FIG. 29 is a plan view showing a state where connection tabs are attached to electrodes on the light receiving surface side and non-light receiving surface side.

FIG. 30 is plan view showing the light receiving surface side of a conventional solar cell element where microcracks are generated.

### DETAILED DESCRIPTION OF PREFERRED EMBODIMENTS

(Solar Cell Element)

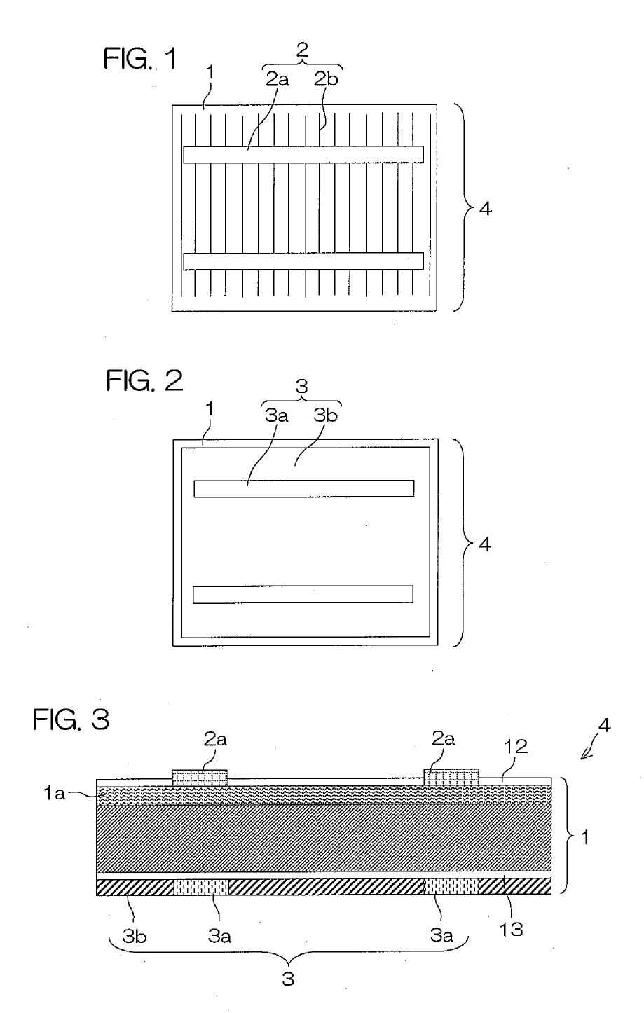

FIGS. 1-3 show a solar cell element according to one embodiment of the present invention, where FIG. 1 is a plan view taken from the light receiving surface side, FIG. 2 is a plan view taken from the non-light receiving surface side and FIG. 3 shows a cross-sectional structure.

In these Figures, the elements are denoted by alphanumeric characters as follows: semiconductor substrate by 1, electrodes on the light receiving surface side by 2, bus bar electrodes on the light receiving surface side by 2a, finger electrodes on the light receiving surface side by 2b, electrodes on the non-light receiving surface side by 3, bus bar electrodes on the non-light receiving surface side by 3a, surface electrode on the non-light receiving surface side by 3b, solar cell element by 4, antireflective film by 12, and non-light receiving surface electric field region (BSF region) by 13.

While the semiconductor substrate 1 may be a monocrystalline semiconductor substrate, multicrystalline semiconductor substrate, amorphous semiconductor substrate, compound semiconductor substrate or the like, crystalline semiconductor substrates such as monocrystalline semiconductor substrate and multicrystalline substrate are taken as example and described in detail.

When, for example, a silicon substrate 1 is used as the semiconductor substrate 1, a p-type silicon substrate 1 doped with a p-type semiconductor dopant comprising B (boron) or the like is employed. A monocrystalline silicon substrate can be obtained by slicing a silicon ingot pulled by the CZ method. A multicrystalline silicon substrate 1 can be obtained by slicing a silicon ingot produced by casting or cutting a sheet-like multicrystalline silicon formed by the ribbon-to-ribbon method (for example EFG (Edge-defined Film-fed Growth) method) or the like.

On the light receiving surface side of the semiconductor substrate, bus bar electrodes 2a and finger electrodes 2b are provided. On the non-light receiving surface side opposite thereto, a surface electrode 3b and bus bar electrodes 3a are provided.

In particular, when the foregoing p-type semiconductor substrate 1 is used, it is a general practice to use aluminum that functions as a p-type semiconductor dopant as a main component for the surface electrode 3b on the non-light receiving surface side. To form the surface electrode 3b, for example, after aluminum paste is applied by screen printing, heat treatment is carried out. By this heat treatment, a p+ region (non-light receiving surface electric field region 13) including a semiconductor dopant such as aluminum at a high concentration is formed on the non-light receiving surface side of the semiconductor substrate 1. The non-light receiving surface electric field region 13 is also called BSF (Back Surface Field) region and has a function to reduce the ratio of recombination loss of photo-induced carriers arriving at the surface electrode 3b, so that photoelectric current density Jsc is improved. In addition, since minority carrier (electron) density is reduced in this non-light receiving surface electric field region 13, it functions to reduce the amount of diode current (dark current) in regions in contact with this non-light receiving surface electric field region 13 and the surface electrode 3b, so that open circuit voltage Voc is improved. As a result, it contributes to improving the properties of the solar cell.

Meanwhile, electrodes composed mainly of a low resistivity material with good solder wettability such as silver are usually used for the electrodes 2 (bus bar electrodes 2a, finger electrodes 2 b) on the light receiving surface side and bus bar electrodes 3a on the non-light receiving surface side shown in FIGS. 1 and 2. As a process for forming such electrodes, a process in which silver paste is applied to the bus bar electrodes 2a, finger electrodes 2b and bus bar electrode 3a by screen printing or the like, then they are baked may be recited.

Furthermore, as shown in FIG. 3, P (phosphorus) atoms are diffused on the light receiving surface side of the semiconductor substrate 1 to form an n-type opposite conductivity-type diffusion layer 1a that is of the opposite conductivity type to p-type. In the foregoing way, a solar cell element 4 having a pn junction is fabricated. In addition, providing an antireflection film 12 comprising silicon nitride, silicon oxide or the like on the light receiving surface side of the semiconductor substrate 1 allows light reflected at the surface of the semiconductor substrate 1 to be advantageously reintroduced into the semiconductor substrate 1, so that the properties of the solar cell can be improved.

(Solar Cell Module)

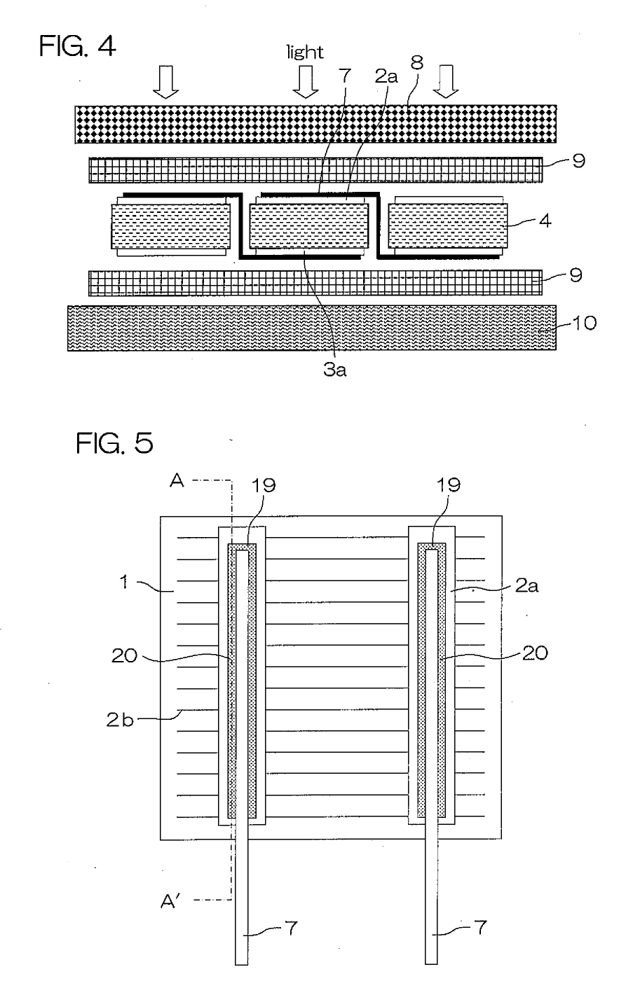

A solar cell module constructed using solar cell elements 4 produced in the foregoing manner is shown in FIG. 4. In the Figure, connection tabs are denoted by 7, a translucent member is denoted by 8, a filler is denoted by 9, and a non-light receiving surface sheet/protective member is denoted by 10. Hereinafter, an explanation will be given of these elements.

A substrate made of glass, polycarbonate resin or the like is used as the translucent substrate 8. For the glass plate, although white sheet glass, tempered glass, double-strength glass, heat reflecting glass or the like may be used, clear tempered glass about 3 mm-5 mm in thickness is commonly used. On the other hand, when a substrate made of synthetic resin such as polycarbonate resin is used, those having a thickness of 5 mm or so are commonly used.

The filler 9 is composed of ethylene vinyl acetate copolymer (EVA) or polyvinylbutyral (PVB), which is formed into a sheet-like shape with thickness of about 0.4-1 mm by an extruder having a T-die (plate-like head). These are heated and pressed under a decreased pressure by a laminating machine, by which they are softened and fused to be integral with other members.

While EVA and PVB are occasionally colored in white and the like by mixing titanium oxide or pigments, the filler 9 on the light receiving surface side of a solar cell module of the present invention is kept to be transparent, because coloring the filler reduces the amount of light incident on the solar cell element, leading to decrease in power generating efficiency.

EVA and PVB used for the filler 9 on the non-light receiving surface side may be transparent or colored in white by mixing titanium oxide or pigments so as to match the peripheral environment of the place where the solar cell module is installed.

For the non-light receiving surface sheet/protective member 10, a fluorine-based resin sheet with weatherability that includes aluminum foil held inside to stop water permeation or a polyethylene terephtalate (PET) sheet that is vapor-deposited with alumina or silica may be employed, which may be transparent or colored in white, black or the like.

As shown in FIG. 4, a connection tab 7 is formed to extend generally full lengths of the bus bar electrodes 2a, 3a, and electrically interconnect bus bar electrodes 2a, 3a of adjacent solar cell elements 4, or electrically or mechanically connect the solar cell elements 4 to side wiring (not shown).

The solar cell module with connection tabs 7 connected thereto is, usually, mounted on a laminate including the translucent member 8 and the filler 9 on the light receiving surface side stacked thereon, and after the filler 9 on the non-light receiving surface side and protective member 10 are further stacked successively, they are integrated into one piece through a laminating process. Thereafter, a frame member (not shown) and a terminal box (not shown) are attached so as to produce a solar cell module with weatherability.

The terminal box (not shown) mounted on the protective member 10 by means of a bonding material or the like is provided for transmitting output electric power from the solar cell element 4 to an external circuit. For example, this terminal box is formed using denatured polyphenylene ether (denatured PPE resin) and colored in black taking light resistance to ultraviolet rays and the like into consideration. Also, the terminal box is separated into a main body and a cover part so as to facilitate soldering and the like after the mounting, in which the cover part is fixed to the main body by fitting in or screwing in. The size of the terminal box may be determined to be optimum in accordance with the size of the solar cell module on which it is mounted. One example of commonly used terminal boxes is one that has a side length of about 5-15 cm, and a thickness of 1-5 cm.

In addition, the frame member (not shown) is provided for securing mechanical strength and weatherability that are required for a solar cell module, and also for connecting and fixing a base (not shown) to the solar cell module in the case of its installation outdoors. The frame member is formed using aluminum or resin taking strength and cost required for the solar cell module into consideration. When aluminum is used to form a frame member, aluminum is extrusion molded followed by anodization and clear coating on its surface.

In fabricating the solar cell module, the filler 9 on the light receiving surface side is disposed on the translucent substrate 8, on which the solar cell elements 4 interconnected by means of the connection tabs 7 is mounted. Then, the filler 9 on the non-light receiving surface side and the protective member 10 are further mounted successively thereon. This laminate in this state is set in a laminator and heated at 100-200° C. for 15 minutes to 1 hour under decreased pressure, by which these are integrated into one piece. A module frame or the like is attached to this integrated piece, thereby producing a complete solar cell module.

Interconnection between the solar cell elements 4 by the connection tabs 7 may be made by series connection and parallel connection. When the solar cell elements 4 are interconnected in series, one end of a connection tab 7 is connected to a bus bar electrode 2a of one solar cell element 4 by means of a conductive bonding material such as solder, and the other end thereof is connected to a bus bar electrode 3a of another solar cell element 4 by means of a conductive bonding material such as solder. In the case of parallel connection, one end of a connection tab 7 is connected to a bus bar electrode 2a (3a) of one solar cell element 4, and the other end thereof is connected to a bus bar electrode 2a (3a) of another solar cell element 4.

These connection tabs 7 are made of a metal material with good conductivity such as copper, silver, palladium, silver-palladium alloy, gold, nickel, solder, lead or the like. When this metal material is solder coated or a surface metal film is additionally provided by vapor deposition, plating or the like, not only conductivity is secured, but also the connection tabs 7 can be more advantageous in terms of corrosion resistance and oxidization decrease.

Meanwhile, it is preferable to use copper foil for the connection tabs 7 considering its conductivity and easiness in solder coating. Specifically, one surface of a copper foil about 0.1-1.0 mm in thickness and about 5-15 mm in width is coated with solder of 20 to 70 Mm thickness to obtain a connection tab 7.

In particular, when it is connected to a bus bar electrode 2a on the light receiving surface side, the width of the connection tab is preferably equal to or smaller than the width of the bus bar electrode 2a so as not to cast a shadow on the light receiving surface of the semiconductor substrate 1. The length of each connection tab 7 for interconnecting solar cell elements 4 is designed to almost overlap the bus bar electrode 2a (3a) of the solar cell element 4 for reducing electrical resistance of the entire solar cell module. When a typical 150 mm square multicrystalline silicon solar cell element 4 is used, the width of the connection tab 7 is about 1-3 mm, and the length is about 200-300 mm.

A solar cell module according to the present invention is characterized in that a fillet with a predetermined shape is formed on side surfaces on the shorter length sides of each connection tab 7 so that the foregoing electrodes 2a, 3a and end portions of the connection tab 7 are fixated to each other.

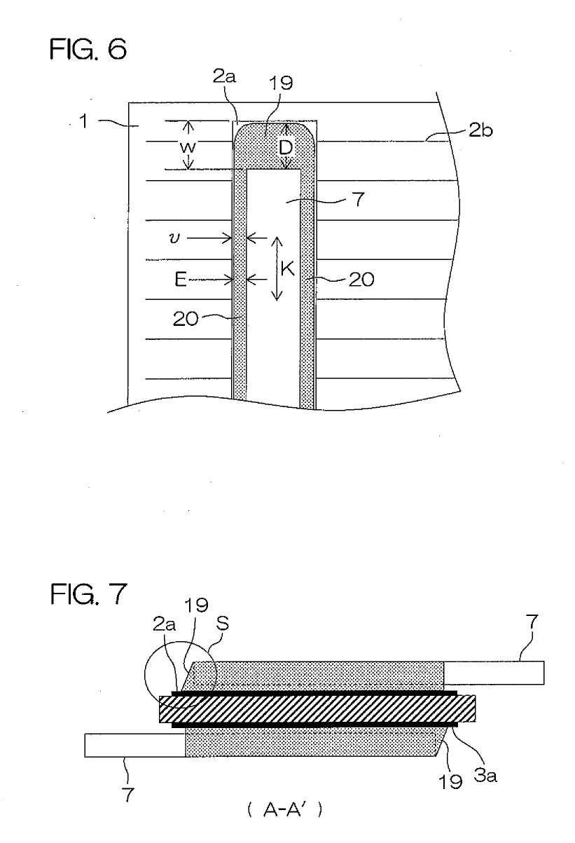

FIG. 5 is a plan view showing the light receiving surface side of a solar cell element 4 with connection tabs 7 of the present invention attached thereto. FIG. 6 is an enlarged view of a region in the vicinity of a shorter length side of a connection tab 7. FIG. 7 is a cross-sectional view of the solar cell element 4 taken along the line A-A′ in FIG. 5.

In the solar cell element 4 according to the present invention, the bus bar electrodes 2a, 3a, and connection tabs 7 have elongated shapes as rectangles having shorter sides and longer sides. However, the shape of the connection tab 7 is not limited to the simple rectangle, but may be a deformed rectangular shape that includes notches in the longer sides. In addition, a fixation member for fixating both of side surfaces on the shorter length sides of the connection tab 7 and the bus bar electrodes 2a, 3a is provided. This fixation member is referred to as “shorter length side-fixation member”. By this shorter length side-fixation member, a fillet 19 is formed on side surfaces on the shorter length sides of the connection tab 7.

Moreover, a fixation member for fixating both of side surfaces on the longer length sides of the connection tab 7 and the foregoing bus bar electrodes 2a, 3a is further provided. This fixation member is referred to as “longer length side-fixation member”. By this longer length side-fixation member, a fillet 20 is formed on side surfaces on the longer length sides of the connection tab 7.

As shown in FIG. 6, in order to form fillets 19, on the side surfaces of a connection tab 7, the connection tab 7 is mounted so that it is apart from an end of the bus bar electrode 2a, 3a by a length w, and apart from a longer side of the bus bar electrode 2a, 3a by a length v.

In a solar cell element 4 according to the present invention, the relationship between the distance w from an end of the bus bar electrode sa, 3a to a shorter length side of the connection tab 7 and the distance v from a longer length side of the bus bar electrode 2a, 3a to a longer length side of the connection tab 7 satisfies w>v.

To take an example of the numeric values, when the width of a shorter length side of a bus bar electrode 2a, 3a is 1.6 mm, and the width of a shorter length side of connection tab 7 is 1.3 mm, w=2-3 mm, v=0.15 mm.

A width of protrusion of a fillet 19 from an end surface on the shorter length side of a connection tab 7 is represented by D, and a width of protrusion of a fillet 20 from a longer length side of the connection tab 7 is represented by E. Since the foregoing relationship w>v is satisfied, the protrusion width D of fillet 19 and the protrusion width E of fillet 20 also satisfy the relationship expressed as D>E.

The reason for the large protrusion width D of fillet 19 is that because of the elongated shapes of the bus bar electrodes 2a, 3a and connection tabs 7, stress is generated in the solar cell element 4 mainly along the longitudinal direction K (See FIG. 6). In order to relieve this stress, forming the fillet 19 so that the protrusion width D at the shorter length sides of the connection tab 7 is large is most effective. On the other hand, stress generated in a direction perpendicular to the foregoing longitudinal direction K is relatively small. Accordingly, in view of stress relieving, designing the protrusion width E of fillet 20 to be large will have no significant effect. When the width of the connection tab 7 is narrowed so that the protrusion width E of fillet 20 is longer, the area where the bus bar electrodes 2a, 3a overlap the connection tab 7 is reduced, which disadvantageously causes the amount of electric current to decrease. Therefore, the protrusion width D of fillet 19 is designed to be large and the protrusion width E of fillet 20 is designed to be small, thereby satisfying two requirements including stress relieving and increasing the overlapping area.

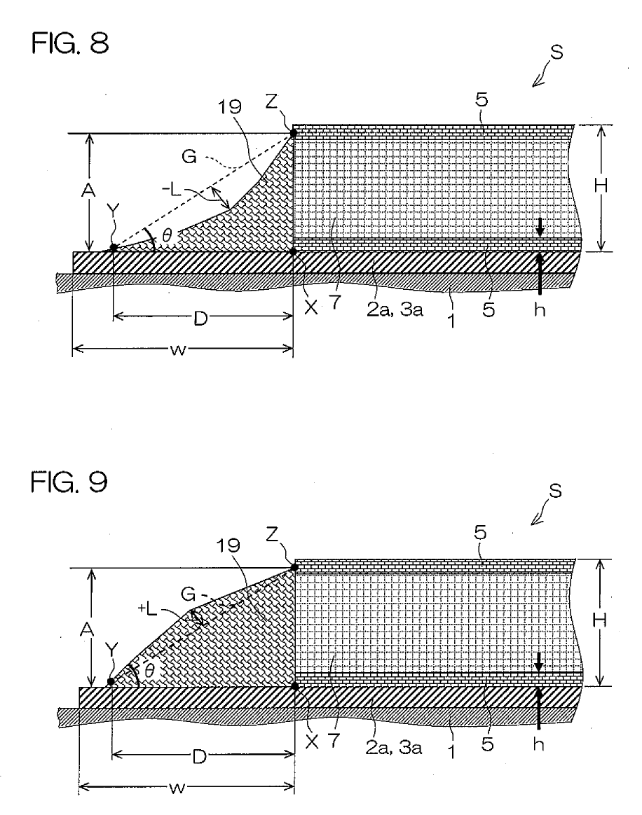

FIGS. 8-11 show enlarged cross-sectional views of the part S near an end portion of the connection tab 7 shown in FIG. 7.

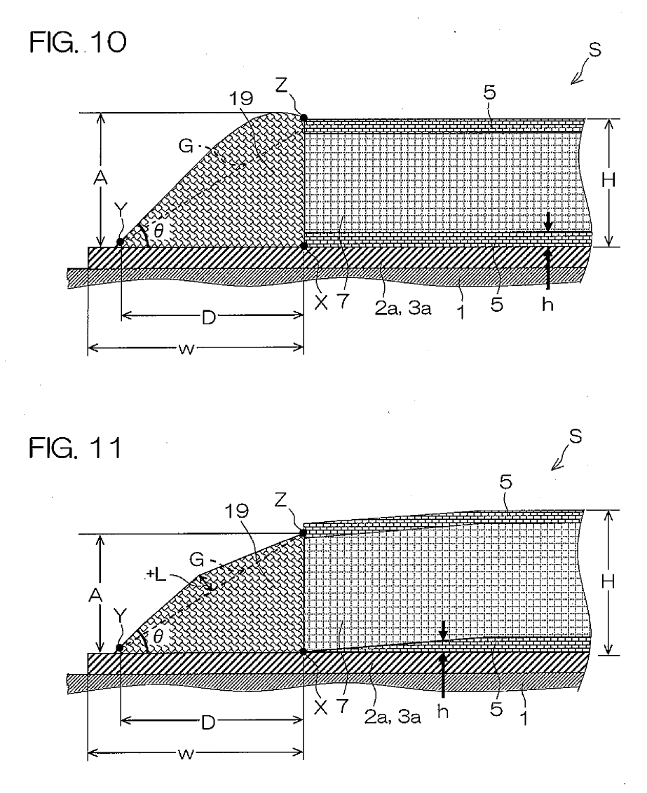

FIG. 8 illustrates a case where the fillet 17 has an indentation in cross-sectional view, and FIG. 9 illustrates a case where the fillet 19 has a bulge in cross-sectional view. FIG. 10 illustrates a case where the fillet 19 grows higher than the connection tab 7. Since the connection tab 7 mounted on the non-light receiving surface bus bar electrode 3a has the same structure, hereinafter, the light receiving-surface bus bar electrode 2a and the non-light receiving surface bus bar electrode 3a are collectively referred to as “bus bar electrode 2a, 3a”.

Although the material for the fixation member for forming the fillet 19 may be non-conductive resin, conductive resin or the like and is not limited to a specific kind, it is referred to as “solder” in the examples below. In addition, the surface of the connection tab 7 is preliminarily coated with a coating layer 5. The coating layer 5 may be composed of eutectic solder, lead-free solder, or a conventionally known conductive adhesive. The component is not limited to a specific kind, but may be of any kind so long as it is capable of electrically and mechanically connecting the connection tab 7 and bus bar electrode 2a, 3a. Hereinafter, unless defined otherwise, the description will proceed assuming that the coating layer 5 is formed of solder. To coat the surface of the connection tab 7 with the coating layer 5, a method such as solder dipping, solder plating or the like is used.

A height of the connection tab 7 measured from the electrode surface of the bus bar electrode 2a, 3a (including the thickness of the coating layer 5) is represented by H, and a height of the coating layer 5 at a joint surface between the connection tab 7 and bus bar electrode 2a, 3a is represented by h. A peak point of a boundary where the fillet 19 is in contact with the connection tab 7 is represented by Z, and a height of the fillet 19 measured from the electrode surface of the bus bar electrode 2a, 3a to the point Z is represented by A. In addition, a point on the bus bar electrode 2a, 3a located on a line vertically descending from the point z is represented by X.

A point on the surface of the fillet 19 at which the thickness of the fillet 19 on the bus bar electrode 2a, 3b is 1% or less of A is represented by Y, and a line segment connecting the point Z to the point Y at the shortest distance is defined as line segment G. An angle that this line segment G and the bus bar electrode 2a, 3a make is represented by θ. In addition, a protrusion width of fillet 19 measured from an end surface of the connection tab 7 to the point Y is represented by D.

When the surface of the fillet 19 is present on the side of semiconductor substrate 1 with respect to the line segment G (in other words, when the surface of the fillet 19 has an indentation), the longest distance in vertical distances from the line segment G to the surface of fillet 19 is defined as indentation amount −L (See FIG. 8). When the surface of the fillet 19 is present on the side opposite to the semiconductor substrate 1 with respect to the line segment G (in other words, when the surface of fillet 19 has a bulge), the longest distance in vertical distances from the line segment G to the surface of fillet 19 is defined as bulge amount +L (see FIG. 9).

An example where the surface of fillet 19 grows higher than the height H of connection tab 7 is shown in FIG. 10. In this case, the height A of the fillet 19 is greater than the height H of the connection tab 7.

It is preferable that the foregoing protrusion width D of the fillet 19 is 30-300% of the height H of the connection tab 7. This is because a protrusion width D that is less than 30% of the height H of the connection tab 7 causes the connecting strength to weaken, and fails to adequately relieve stress generated in the solar cell element along the longitudinal direction K, and therefore cracks are prone to occur in the solar cell element 4. On the other hand, when a protrusion width D exceeds 300% of the height H of the connection tab 7, although stress can be relieved, a vertically viewed length of the part where the connection tab 7 and the bus bar electrode 2a, 3b electrically overlap each other is reduced, which may cause the efficiency of the solar cell element to deteriorate.

The angle θ made by the line segment G and the bus bar electrode is preferably 7°-60°. When the angle θ is more than 60°, the connection strength weakens as in the case of too small protrusion width D, and stress generated on the surface of the solar cell element along the longitudinal direction K cannot be relieved adequately. When the angle θ is less than 7°, the overlapping length between the connection tab 7 and the bus bar electrode 2a, 3a decreases. Accordingly, this may cause the properties of the solar cell element to be degraded.

The thickness h of the solder layer at a junction surface of the connection tab 7 on the side to be connected to the bus bar electrode 2a, 3a is preferably between 5 μm and 100 μm as later described.

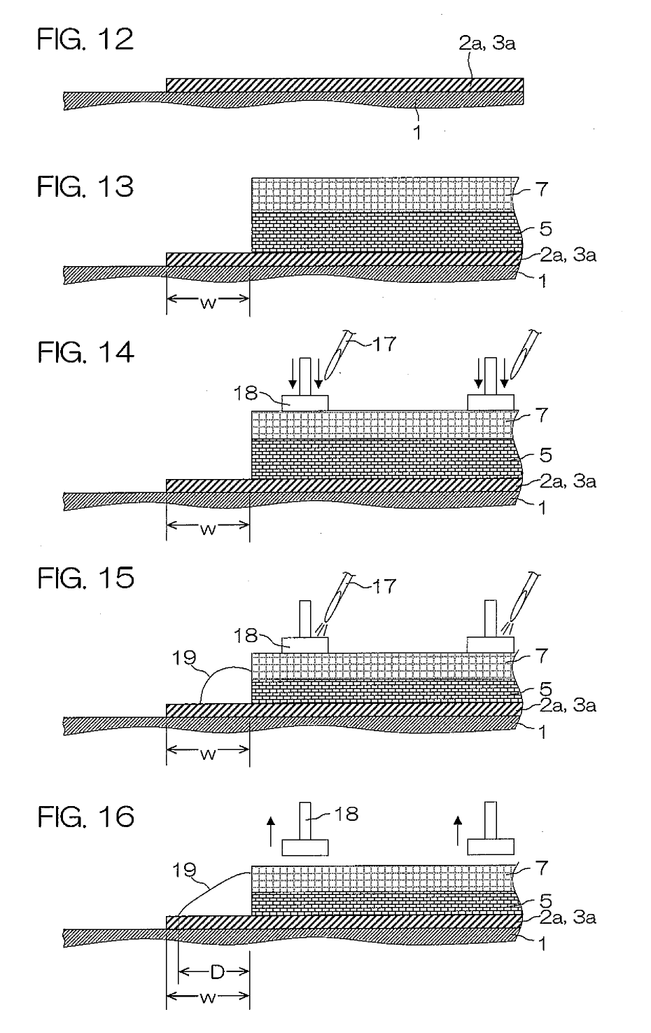

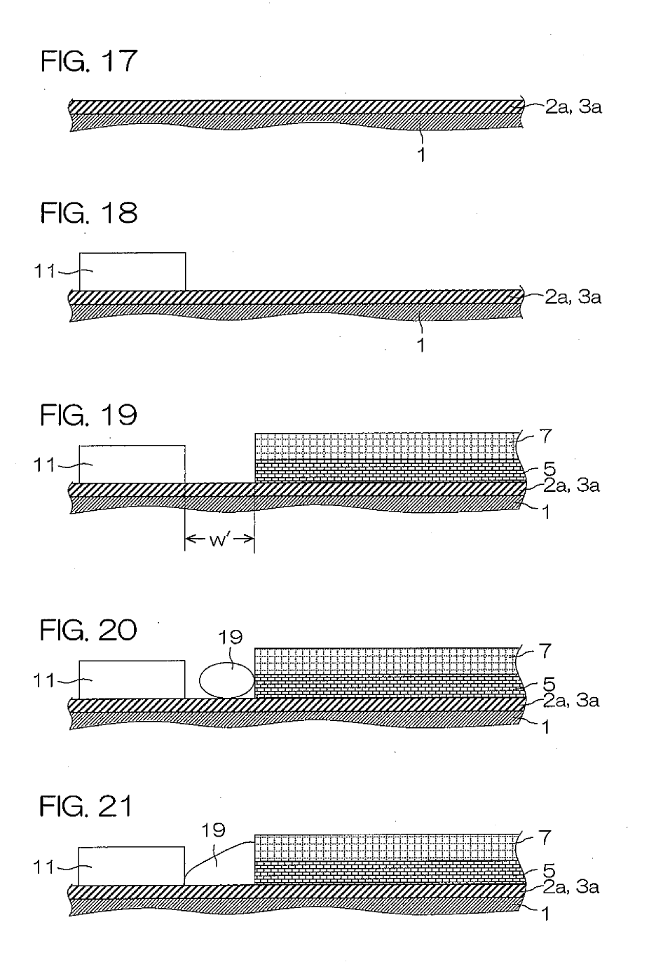

The solder for forming such a fillet 19 may be, as in the manufacturing process of solar cell module that will be later described referring to FIGS. 12-16, a solder supplied from a coating layer 5 in a junction surface between connection tab 7 and semiconductor substrate 1, or an externally provided solder as in the manufacturing process of solar cell module later described referring to FIGS. 17-21.

In the case of a solder supplied from the coating layer 5, as a result of the supply from the coating layer 5, in the solder coating layer at a junction surface between the connection tab 7 and semiconductor substrate 1, the height h of the solder coating layer near the end portions of the connection tab 7 is smaller.

FIG. 11 is a cross-sectional view showing a state where the solder coating layer near an end portion of the connection tab 7 becomes thinner. The thickness h of the solder coating layer gradually becomes smaller as the location nears the end surface of the connection tab 7. As a result, the height H of the connection tab 7 gradually becomes smaller in the region S near the end portion. Specifically, when compared to the height H of the connection tab 7, a height H of the connection tab 7 in a region S near the end portion is decreased by 5 μm-20 μm.

In addition, in one embodiment of the present invention, an indentation amount −L of the fillet 19 is 0 to −54% (−0.54≦−L/A≦0) of a height A of the fillet 19, or a bulge amount L of the fillet 19 is 0 to 10% (0≦L/A≦0.1) of a height A of the fillet 19. The conditions above are expressed as the following one equation:
−0.54≦L/A≦0.1

An indentation amount −L that is smaller than −54% (absolute value of L is larger than 54%) of the height A causes the volume of the fillet 19 to be too small, and therefore stress generated by shrinkage of the connection tab 7 during the process for welding the connection tab 7 to the bus bar electrode 2a, 3a cannot be dispersed adequately. As a result, cracks occur in the solar cell element 4. In particular, cracks are prone to generate in the vicinity of the point X in FIG. 8.

When a bulge amount L exceeds 10% of the height A, the volume of the fillet 19 is too great, and therefore stress due to shrinkage of the fillet 19 becomes great, which causes cracks to occur in the solar cell element 4. In particular, cracks are prone to generate in the vicinity of the point Y in FIG. 8.

Now, the relationship between height A of the fillet 19 and height H of the connection tab 7 is described.

FIGS. 8 and 9 show cases where height A of fillet 19 is smaller than height H of connection tab 7, and FIG. 10 shows a case where height A of fillet 19 is larger than height H of connection tab 7.

It is preferred that the height A of the fillet 19 is in the range of −90% to +20% of the height H of the connection tab 7. When the ratio of the height A to the height H of the connection tab 7 is smaller than −90%, the stress relieving effect is weakened. When an excessive amount of solder is present at a ratio greater than +20%, stress becomes too great, hindering exertion of the stress relieving effect.

Meanwhile, the height A of the fillet 19 is more preferably in the range of −20% to +20% of the height H of the connection tab 7.

For example, when the height H of the connection tab 7 is 0.3 mm, the height A of the fillet 19 is preferably 0.24-0.36 mm.

As described above, by the structure in which the fillet 19 is formed to have a height A which is −90% to +20% of the height H of the connection tab 7, the cross-sectional area of the solder is increased allowing the maximum principal stress to be dispersed, and since the solder is allowed to have a sufficient volume, an effect that solder in this part itself is deformed according to the stress can be achieved. This allows the fillet 19 to relieve stress generated in the principal surface of the semiconductor substrate 1, making it possible to eliminate generation of microcracks.

Incidentally, as the fixation member for forming the fillet 19, materials other than solder may be used. Non-conductive resins, conductive resins may be recited as the materials. Conductive resins are especially profitable.

Examples of non-conductive resins are epoxy resin, urethane resin, polyimide resin and silicon resin.

Examples of conductive resins are resins to which silver or carbon is incorporated in the non-conductive resin as a filler. Further, iodide doped polyacetylene (conductive polymer) may be used.

(Manufacturing Process of Solar Cell Module 1)

Hereinafter, a manufacturing process of a solar cell module will be described referring to FIGS. 12-16.

This manufacturing process of a solar cell module is a process in which with a coating layer 5 of a connection tab 7 being in a molten state, the bus bar electrode 2a, 3a is pressed relative to the connection tab 7 so that the solder of the coating layer 5 is pushed out between an end portion of the connection tab 7 and the bus bar electrode 2a, 3a, thereby supplying the material for a fillet 19.

(a) As shown in FIG. 12, a semiconductor substrate 1 including a bus bar electrode 2a, 3a on one principal surface thereof is prepared.

(b) As shown in FIG. 13, a connection tab 7 is disposed through a coating layer 5 in a region on the bus bar electrode 2a, 3a, at a location apart from an end of the connection tab 7 by a predetermined distance w.

The connection tab 7 is formed such that a wiring material for connection of solar cell elements with a low electric resistance such as copper or aluminum is coated with a solder in a zone-like manner by plating or dipping so that the solder with a thickness h on the order of 5 μm to 100 μm covers at least a surface on the side in contact with the bus bar electrode, which is then cut into appropriate lengths to be used. The solder may be a tin-lead eutectic solder or lead-free solder.

When the thickness h of the coating layer 5 is less than 5 μm, there may be cases where the fillet 19 cannot be formed to be close to the height H. When the thickness h exceeds 100 μm, the excessive solder has a height greater than the height H of the connection tab 7, which causes stress to increase, causing microcracks to generate. Accordingly, the thickness h of the foregoing solder layer on the side to be connected to the foregoing bus bar electrode 2a, 3a is determined to be from 5 μm to 100 μm, so that the fillet can be easily formed and the stress relieving effect can be reliably achieved.

(c) As shown in FIG. 14, pushing pins 18 are placed on predetermined positions on the connection tab 7 so that the connection tab 7 is pressed against the bus bar electrode 2a, 3a. There are a plurality of pushing pins 18 to press the connection tab 7 at a plurality of positions so that the force is applied uniformly to the connection tab 7. Meanwhile, since end portions of the connection tab 7 are prone to be detached from the solar cell element 4 particularly due to waving, it is preferred to provide points to which pressure is applied within a distance of 20 mm from the ends of the connection tab 7 so as to ensure the formation of the fillet 19 in the end portions.

(d) Subsequently, as shown in FIG. 15, hot air at a temperature of 400° C.-500° C. is blown through hot air jet nozzles 17 to locations around the pushing pins 18 for a predetermined duration of time, for example, for 1 or 2 seconds so as to melt the coating layer 5, by which the connection tab 7 and bus bar electrode 2a, 3a are connected to each other. During this step, by pressing with pushing pins 18 with the coating layer 5 being in a molten state, it is possible to supply the fillet 19 comprising solder to an end surface on the shorter length side of the connection tab 7 on the bus bar electrode 2a, 3a. At this time, since the solder wettability of the semiconductor substrate 1 itself is poor, the solder will not extend beyond the end portion of the bus bar electrode 2a, 3a, but stays before the end portion of the bus bar electrode 2a, 3a.

(e) Thereafter, when the solder is solidified, the pushing pins 18 are lifted as shown in FIG. 16. Since the molten fillet 19 is cooled and solidified by heat dissipation, it is possible to form the fillet 19 to have desired thickness and shape in the end portion of the connection tab 7 in a condition where the bus bar electrode 2a, 3a and the connection tab 7 are connected to each other. During this, by controlling the pressing force of the pushing pins 18 and the thickness of the coating layer 5 interposed between the connection tab 7 and bus bar electrode 2a, 3a, the amount of the fillet 19 to be supplied can be controlled.

Through the foregoing steps, the connection tab 7 can be soldered to the respective bus bar electrodes 2a, 3a on the light receiving surface side and non-light receiving surface side of the solar cell element 4.

By the foregoing manufacturing process of solar cell module, it is possible to connect the connection tab 7 to the bus bar electrode 2a, 3a through the coating layer 5, and also to supply the coating layer 5 to the end portion of the connection tab 7 as the fillet 19 at the same time, which is advantageous because the cycle time during the manufacturing of a solar cell module can be minimized.

In addition, since the coating layer 5 interposed between the connection tab 7 and the bus bar electrode 2a, 3a and the fillet 19 can be sequentially formed using the same solder material, formation of an oxide film or the like constituting a resistance component between the coating layer 5 and fillet 19 can be restricted, which is also advantageous from a point of view of electric properties of the solar cell module.

Moreover, since the fillet 19 and coating layer 5 are joined to the bus bar electrode 2a, 3a by means of the same solder material, formation of boundaries at junction surfaces can be restricted, which is therefore advantageous also in terms of the bonding strength between the bus bar electrode 2a, 3a and the connection tab 7.

Furthermore, the use of pushing pins 18 is also preferable because it provides, in addition to the foregoing effects, the effect that the connection tab 7 on the bus bar electrode 2a, 3a hardly deviate laterally from the width of the bus bar electrode 2a, 3a, it is possible to check decrease in contact area between the connection tab 7 and the bus bar electrode 2a, 3a and decrease in power generating efficiency of the semiconductor substrate 1 due to the connection tab 7 casting shadows, in particular, on the light receiving surface side of the semiconductor substrate 1.

Meanwhile, a solder resist with poorer solder wettability than that of the bus bar electrode 2a, 3a may be formed in an end portion of the bus bar electrode 2a, 3a. Forming a solder resist can reliably stop the solder from extending beyond the end portion of the bus bar electrode 2a, 3a.

When the desired thickness cannot be achieved for the solder of the formed fillet 19, by providing an additional solder material between the end portion of the connection tab 7 and the bus bar electrode 2a, 3b, and melting it during the formation of the fillet 19, a sufficient thickness of the solder of the fillet 19 can be achieved. The additional solder material may comprise a solder material having the same properties as the fillet 19, or a solder material having different properties.

In order to form this additional solder (referred to as the second solder), a solder material in a molten state is additionally supplied between an end portion of the connection tab 7 and the bus bar electrode 2a, 3a. The second solder formation may be carried out such that the solder material is preliminarily brought into a molten state to be poured on the bus bar electrode 2a, 3a, or a solid solder material is held at an end portion of the connection tab 7 on the bus bar electrode 2a, 3a, and it is melted at a predetermined temperature. As described above, it is preferable to supply an additional solder material on the bus bar electrode 2a, 3a and melt it, because the solder of the fillet 19 can be formed to have a larger thickness by addition of the second solder material.

(Manufacturing Process of Solar Cell Module 2)

Here, another manufacturing process of solar cell module in which a fillet 19 with a predetermined thickness is formed at an end portion of a connection tab 7 will be described in detail with reference to FIGS. 17-21.

(a) First, as shown in FIG. 17, a semiconductor substrate 1 including bus bar electrode 2a, 3a on one principal surface thereof is prepared.

(b) Then, as shown in FIG. 18, a solder resist 11 having poorer solder wettability than that of the bus bar electrode 2a, 3a is formed at a predetermined region on the bus bar electrode 2a, 3a.

The solder resist 11 may be formed using glass, thermosetting resin, UV-curable resin, or other known materials having poorer solder wettability than the electrode and connection tab 7 to be later described.

Various methods may be employed to form the solder resist 11 on a predetermined region on the bus bar electrode 2a, 3a, including screen printing, vapor deposition, applying a resin or the like with a spatula, etc.

(c) As shown in FIG. 19, a connection tab 7 is disposed through a coating layer 5 at a region on the bus bar electrode 2a, 3a that is apart from the region where the solder resist 11 is formed by a predetermined distance w′. As a matter of course, the connection tab 7 has solder wettability better than that of the solder resist 11.

(d) Subsequently, as shown in FIG. 20, a solder that is the material for the fillet 19 is supplied to a region on the bus bar electrode 2a, 3a between an end portion of the connection tab 7 and the solder resist 11.

This solder may be an eutectic solder or lead-free solder. The method of supplying this solder may be pouring the solder material that is preliminarily brought into a molten state on the bus bar electrode 2a, 3a between the end portion of the connection tab 7 and the solder resist 11, or holding a solid solder on the bus bar electrode 2a, 3a between the end portion of the connection tab 7 and the solder resist 11, and then melting it at a predetermined temperature.

Thereafter, before the solder material is solidified, hot air at a temperature of 400° C.-500° C. is brown through hot air jet nozzles (not shown) for a predetermined duration of time, for example, 1 or 2 seconds so that the solder is melted, thereby connecting the connection tab 7 to the bus bar electrode 2a/3a.

(e) Thereafter, as shown in FIG. 21, the molten solder is cooled and solidified by heat dissipation to form the fillet 19. Through the steps above, under a condition where the bus bar electrode 2a, 3a is connected to the connection tab 7, a fillet 19 with desired thickness and shape can be formed in the end portion of the connection tab 7.

Incidentally, the reason that a fillet 19 with a predetermined shape can be formed between an end portion of the connection tab 7 and the solder resist 11 by the present invention is assumed as follows:

When a solder is supplied on the bus bar electrode 2a, 3a between an end portion of the connection tab 7 and the solder resist 11, due to its surface tension, the solder is pushed out from the solder resist 11 toward the end portion side of the connection tab 7. As a result, the solder moves from the side of the solder resist 11 to the side of the end portion of the connection tab 7 and is kept in a condition where the amount of solder is larger on the side of the end portion of the connection tab 7 than on the side of the solder resist 11. For this reason, a fillet 19 with desired thickness and shape can be formed.

Accordingly, the shape of the fillet 19 can be changed by changing the amount of the solder supplied on the bus bar electrode 2a, 3a between the connection tab 7 and the solder resist 11, or adjusting the distance w′ between the end portion of the connection tab 7 and the solder resist 11 on the bus bar electrode 2a, 3a. Therefore, when a temperature change occurs and stress is generated caused by the difference in thermal expansion coefficient between the connection tab 7 and the semiconductor substrate 1, the stress can be relieved by the fillet 19.

Incidentally, it goes without saying that the solar cell module and manufacturing process thereof according to the present invention are not limited to the foregoing specific embodiments, but various modifications may be made.

While in one embodiment shown in FIGS. 17-21, after the solder resist 11 is formed on the bus bar electrode 2a, 3a of the semiconductor substrate 1, the connection tab 7 is connected to the bus bar electrode 2a, 3a through the coating layer 5, the process is not limited to this embodiment, but may be such that after the connection tab 7 is connected to the bus bar electrode 2a, 3a through the coating layer 5, the solder resist 11 is formed on the bus bar electrode 2a, 3a.

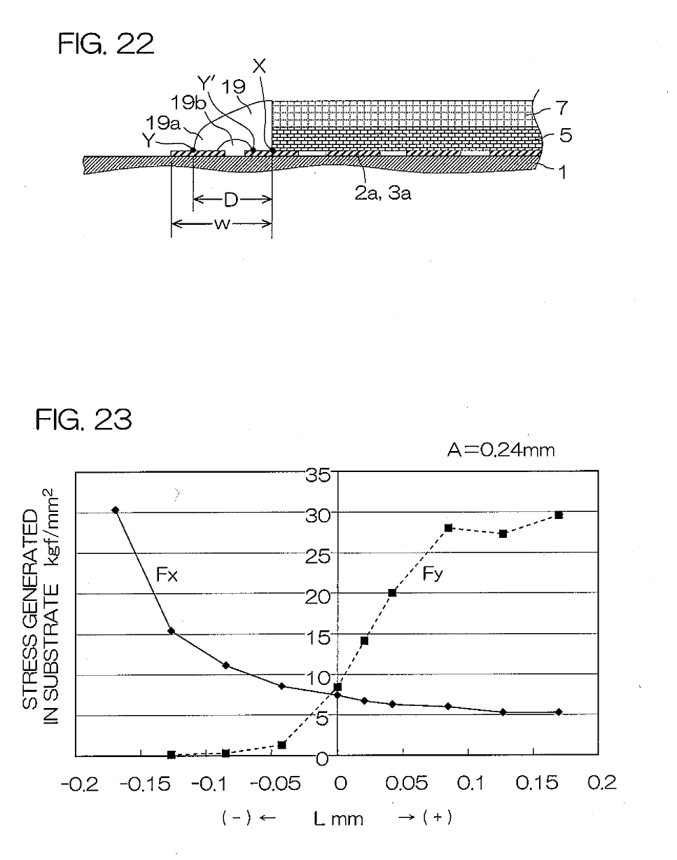

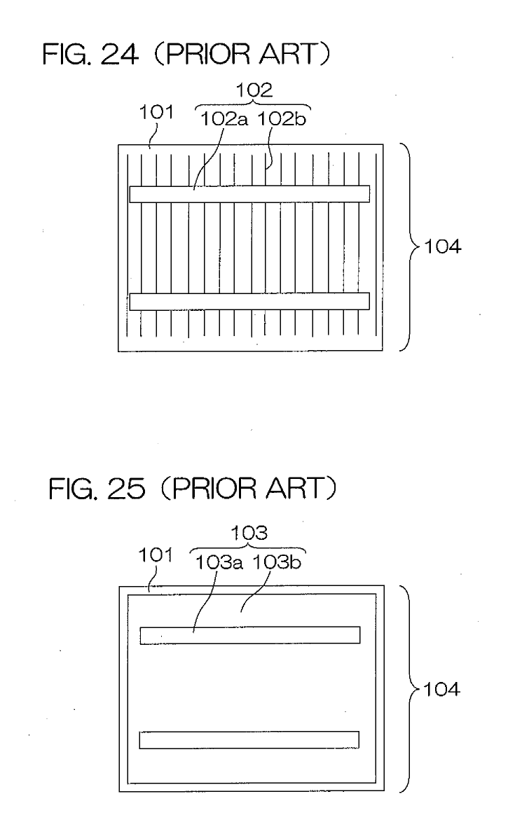

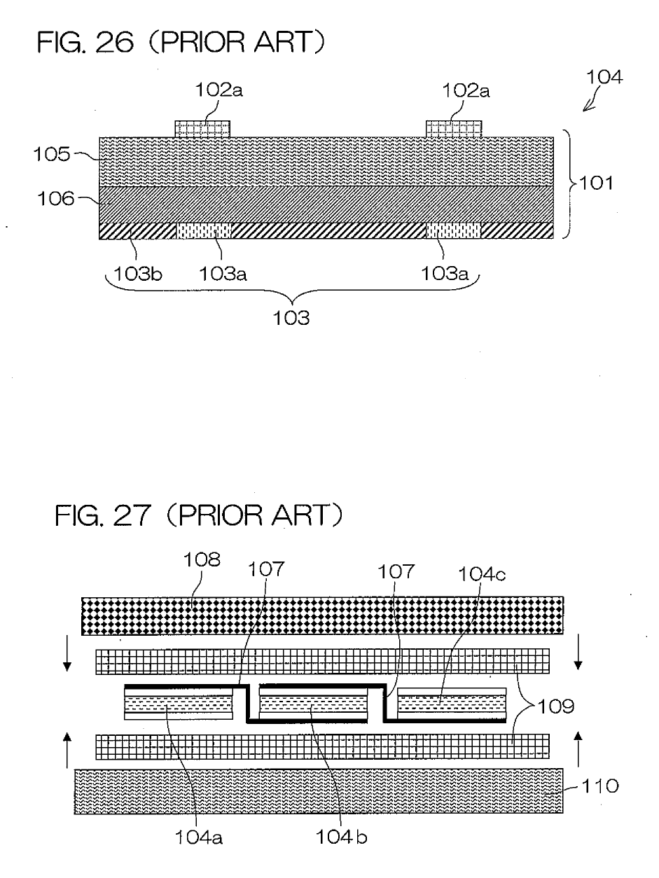

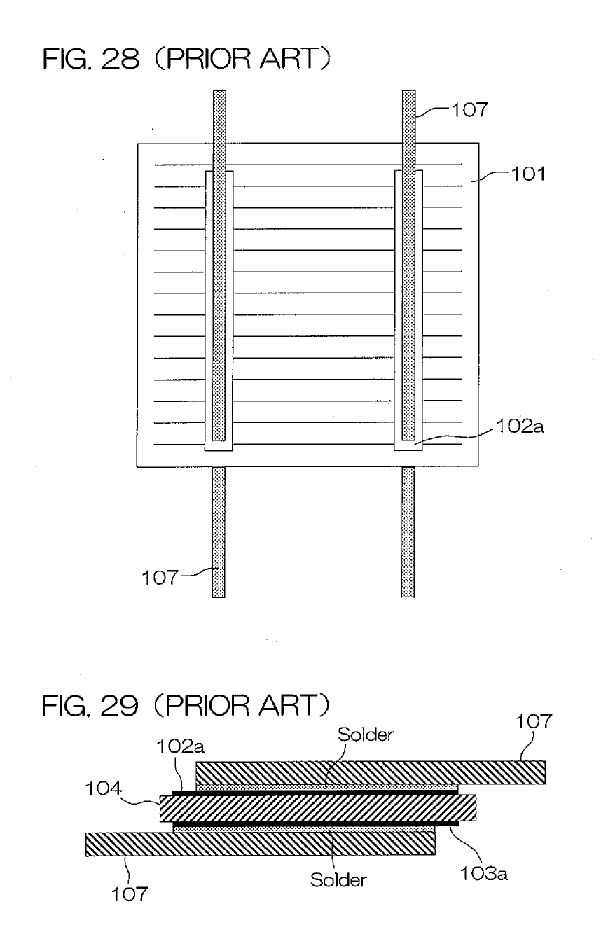

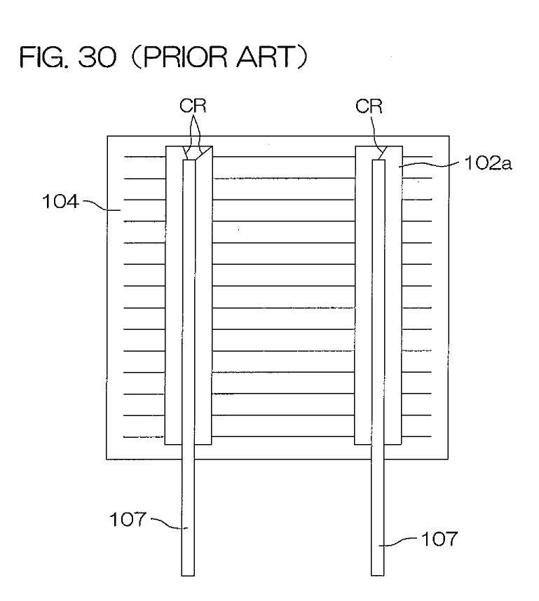

In addition, as explained previously, although an electrode mainly composed silver or the like with good solder wettability and low resistivity is usually used as the bus bar electrode 2a, 3a, as shown in FIG. 22, it is possible to provide a region where such a bus bar electrode is not formed at least in a region within the distance w from an end of the bus bar electrode 2a, 3a to the connection tab 7. A method to provide a region where a bus bar electrode is not formed is using a masked pattern to partially form a region where a bus bar electrode is formed and to partially form a region where a bus bar electrode is not formed. Alternatively, it is possible to form a bus bar electrode on the whole of a predetermined region, and partially form a solder resist thereon. By this arrangement, the fillet 19 is formed on the surface to be fixated to the bus bar electrode 2a, 3a so as to include a first region 19a in contact with the bus bar electrode 2a, 3a and a second region 19b that is surrounded by the first region and is not in contact with the foregoing bus bar electrode. Due to the poor solder wettability of the semiconductor substrate 1 or the solder resist, the second region 19b is formed as a cavity. By providing such a cavity-like second region 19b, stress can be dispersed to three points including X, Y′ and Y shown in FIG. 22. The point Y′ here is a point at which the inner wall of the cavity of the second region 19b and the bus bar electrode 2a, 3a are in contact with each other.

### EXAMPLE 1

Solar cell modules were fabricated with the shapes of the fillet 19 shown in FIGS. 8 and 9 by changing some of height A of the fillet 19, indentation amount −L and bulge amount L. The height A of the fillet 19 was generally the same as the height H of the connection tab 7. Ten samples were prepared for each of L/A and −L/A, and the strengths of stress applied to the substrate 1 after welding the connection tab 7 were calculated.

The samples were prepared in the following way. A damaged layer on the surface of a semiconductor element 1 comprising p-type multicrystalline silicon that has a thickness of 100 μm and outer dimensions of 15 cm by 15.5 cm was etched with NaOH to be cleaned. Then, this semiconductor element 1 was placed in a diffusion furnace to be heated in phosphorous oxychloride (POCl₃) so that phosphorus atoms were diffused in the surface of the semiconductor element 1 to form an n-type region. In addition, a silicon nitride film with a thickness of 850 Å was formed thereon as an antireflective film by the plasma CVD method.

In order to form a surface electrode on the non-light receiving surface side of this semiconductor element 1, an organic electrode material including aluminum powder was applied to almost the entire surface of the non-light receiving surface by screen printing, and thereafter the solvent was evaporated and dried.

Subsequently, an organic electrode material including silver powder was applied by screen printing and then dried to form light receiving surface bus bar electrodes 2a and light receiving surface finger electrodes 2b on the light receiving surface side, and bus bar electrodes 3a on the non-light receiving surface side. This semiconductor element 1 was baked at 650° C. for 15 minutes.

Subsequently, using a solder as a bonding material, a connection tab 7 was welded to the light receiving surface bus bar electrode 2a or non-light receiving surface bus bar electrode 3a.

Connection tab 7 made of copper foil with a thickness of 200 μm was dipped into a molten solder pool so that a solder layer with a thickness of 20 μm was applied to the connection tab 7. Accordingly, the thickness H of the connection tab 7 including the solder layer was 240 μm.

The connection tab 7 was disposed on the bus bar electrode 2a, 3a of the solar cell element 4.

Then, pushing pins 18 were lowered to press the connection tab 7 against the bus bar electrode 2a, 3a. In this condition, hot air at a temperature of about 400-500° C. was issued from nozzles 17 to blow the regions where the foregoing pushing pins 18 were pressing the connection tab 7 against the bus bar electrode 2a, 3a for 1 or 2 minutes, by which the solder of the connection tab 7 and the solder of the bus bar electrode 2a, 3a were melted.

During this step, by supplying a solder in a molten state in the vicinity of the end portion of the connection tab 7, a fillet 19 could be formed. The height A of the fillet 19 was about 240 μm. Then, the hot air is stopped to cool the connection tab 7 so that the connection tab 7 was fixated to the bus bar electrode 2a, 3a.

During the foregoing step, the amount of solder to be supplied was adjusted to produce a plurality of samples in which L/A and −L/A of the fillet 19 were differed.

After producing a plurality of samples as described above, stresses Fx, Fy applied to the semiconductor substrate 1 were calculated, the results of which is shown in Table 1.

TABLE 1

| L(mm) | Fx (kgf/mm²) | Fy (kgf/mm²) |
|---|---|---|
| 0.17 | 5.23 | 29.53 |
| 0.127 | 5.27 | 27.32 |
| 0.085 | 6.01 | 28.05 |
| 0.042 | 6.25 | 19.93 |
| 0.021 | 6.74 | 14.19 |
| 0 | 7.5 | 8.4 |
| −0.042 | 8.6 | 1.32 |
| −0.085 | 11.1 | 0.3 |
| −0.127 | 15.5 | 0.1 |
| −0.17 | 30.3 | |

Stress Fx represents stress applied to the substrate 1 directly under the point X in FIGS. 8-11, and stress Fy represents stress applied to the substrate 1 directly under the point Y in FIGS. 8-11.

FIG. 23 is a graph made based on the data in Table 1. The left half of the graph shows stress Fx in the case of fillet 19 having an indentation amount, and the right half shows stress Fy in the case of fillet 19 having a bulge amount.

Here, in a Weibull distribution where fracture stress (location parameter) is assumed to be 8 kgf/mm², and weibull coefficient is assumed to be 6, the stress value at which the cracking possibility is 10% was calculated to be 15.7 kgf/mm², which was determined to be the threshold value of stress.

According to the graph in FIG. 23, stress Fx increases as −L decreases (as the absolute value L increases). Stress Fy increases as L increases.

The range of L in which stress Fx exceeds the threshold value is L>0.024 kgf/mm². The range of L in which stress Fy exceeds the threshold value is L<−0.13 kgf/mm². Accordingly, assuming that A=0.24 mm, the range in which stress Fx and stress Fy do not exceed the threshold value is:
−0.54≦L/A≦0.1

Therefore, providing a fillet 19 with a shape satisfying this condition can lessen generation of cracks in the semiconductor element 1.

### EXAMPLE 2

An organic electrode material including silver powder was used as the bonding material for welding the connection tab 7 to the light receiving surface bus bar electrode 2a or non-light receiving surface bus bar electrode 3a.

Meanwhile, the “organic electrode material including silver powder” refers to an electrode material in the form of paste composed mainly of silver powder, in which an organic vehicle and glass frit were added, the amounts of which were 10-30 parts by weight and 0.1-5 parts by weight, respectively, with respect to 100 parts by weight of silver. In welding the connection tab 7, a solder in a molten state was supplied to an end portion of the connection tab 7 on the bus bar electrode 2a, 3a, thereby forming a fillet 19. When the shape of the fillet 19 satisfied −0.54≦L/A≦0.1, stress Fx and stress Fy do not exceed the threshold value, and it is expected that no cracking occurs.

1. A solar cell module comprising:
a solar cell element including a bus bar electrode for extracting output electric current;
a connection tab having a shape including shorter length sides and longer length sides, that is superposedly attached to the bus bar electrode so as to be electrically connected to the bus bar electrode; and
a shorter length side-fixation member provided so as to fixate to both the bus bar electrode and an end surface on the shorter length side of the connection tab.

2. The solar cell module according to claim 1, further comprising a longer length side-fixation member that fixates to both the bus bar electrode and side surfaces on the longer length sides of the connection tab.

3. The solar cell module according to claim 2, wherein the length of a part where the shorter length side-fixation member is in contact with the bus bar electrode with respect to the direction of the longer length side is greater than the length of a part where the longer length side-fixation member is in contact with the bus bar electrode with respect to the direction of the shorter length side.

4. The solar cell module according to claim 1, wherein the height of the shorter length side-fixation member from the surface of the bus bar electrode at the highest part in contact with the connection tab is in the range of −90% to +20% with respect to the height of the connection tab.

5. The solar cell module according to claim 1, wherein the length of a part where the shorter length side-fixation member is in contact with the bus bar electrode with respect to the direction of the longer length side is 30-300% with respect to the height of the connection tab.

6. The solar cell module according to claim 1, wherein the geometry of the shorter length side-fixation member in a vertical cross-section with respect to the direction of the longer length side has a part that is bulged upward (in +direction) or indented downward (in −direction) with respect to a straight line that virtually connects the highest part of the shorter length side-fixation member in contact with the connection tab and the longest part of the shorter length side-fixation member in contact with the bus bar electrode with respect to the direction of the longer length side, and
the longest distance between an outer profile of the indented or bulged part and the straight line is −10% to +54% of the height of the shorter length side-fixation member at the highest part from the bus bar electrode.

7. The solar cell module according to claim 1, Wherein in the geometry of the shorter length side-fixation member in a vertical cross-section with respect to the direction of the longer length side, an angle made by a straight line and the bus bar electrode is 7-60°, which straight line virtually connecting the highest part of the shorter length side-fixation member in contact with the connection tab and the longest part of the shorter length side-fixation member in contact with the bus bar electrode with respect to the direction of the longer length side.

8. The solar cell module according to claim 1, wherein the shorter length side-fixation member includes in a surface thereof on the side to be fixated to the bus bar electrode, a first region in contact with the bus bar electrode and a second region that is surrounded by the first region and not in contact with the bus bar electrode.

9. The solar cell module according to claim 1, wherein the bus bar electrode and the connection tab are electrically connected to each other through a conductive bonding member, and the shorter length side-fixation member comprises the same material as that of the conductive bonding member.

10. The solar cell module according to claim 9, wherein the conductive bonding member provided on the connection tab is adapted to be thinner on the side closer to the shorter length side-fixation member than on the side of a central portion of the connection tab.

11. The solar cell module according to claim 9, wherein the conductive bonding member comprises a solder.

12. The solar cell module according to claim 11, wherein the connection tab comprises a strip-shaped metal foil which is coated with a solder layer prior to a step where the connection tab is connected to the bus bar electrode by means of soldering, and the thickness of the solder layer on the side to be connected to the bus bar electrode is 5 μm-100 μm.

13. A manufacturing process of a solar cell module comprising:
preparing a solar cell element including a bus bar electrode for extracting output electric current on one principal surface thereof;
connecting a connection tab through a conductive member to the bus bar electrode by disposing the connection tab on the bus bar electrode to be apart from a shorter length side of the bus bar electrode by a predetermined distance;
supplying a material for a fixation member to an end surface on the shorter length side of the connection tab on the bus bar electrode; and
forming the fixation member into the form of a fillet on the side surface on the side of a shorter length side of the connection tab.

14. The manufacturing process of a solar cell module according to claim 13, wherein the material for the conductive member and the fixation member comprises a solder, and the supply of the material for the fixation member is carried out such that with the conductive member being in a molten state between the bus bar electrode and the connection tab, the bus bar electrode is pressed relative to the connection tab, thereby pushing out the conductive member.

15. The manufacturing process of a solar cell module according to claim 13, further comprising forming a solder resist with poorer solder wettability than that of the bus bar electrode at a predetermined region on the bus bar electrode,
wherein the material for the fixation member is supplied between the solder resist and the connection tab on the bus bar electrode.
